(19) United States
(12) Patent Application Publication
(10) Pub. No.: US 2002/0153906 A1
(43) Pub. Date: Oct. 24, 2002

(54) Method of measuring and selecting polymer layers for effective chromophore poling

(76) Inventors: Dexter George Girton, Santa Clara, CA (US); William Walter Anderson, Half Moon Bay, CA (US)

Correspondence Address: SWIDLER BERLIN SHEREFF FRIEDMAN, LLP, 3000 K STREET, NW, BOX IP, WASHINGTON, DC, 20007, US

(21) Appl. No.: 10/119,317

(22) Filed: Apr. 10, 2002

Related U.S. Application Data
(60) Provisional application No. 60/282,476, filed on Apr. 10, 2001.

(51) Int. Cl. G01R 27/08

(52) U.S. Cl. 324/693

(57) ABSTRACT

A process is given to optimizing polymer layers used in modulators by forming a single polymer film between two cladding layers and measuring the conductivity of the single polymer film whereby polymers may be optimized by selected the highest conductivity

This application is based on Provisional Application No. 60/282,476 filed Apr. 10, 2001.

### FIELD OF THE INVENTION

The present invention relates to polymer modulator fabrication, and more particularly, the invention pertains to methods of improving the process of producing polymer systems. Specifically this invention relates to a process and technique for measuring and selecting polymer layers in polymer systems. More specifically, this invention relates to a method for measuring and selecting polymer layers for effective chromophore poling.

### BACKGROUND OF THE INVENTION

There are several methods used in fabrication of polymers for use in electro-optic devices. An important aspect of polymer preparation is to properly identify materials which can be successfully used in fabrication.

Prior procedures have used optical properties and fabrication characteristics to identify candidate materials for polymer films. The can result in non-optimum voltage sensitivity performance of the planar polymer modulators due to inefficient alignment of the chromophore.

### SUMMARY OF THE INVENTION

By the techniques and methods of this invention, an apparatus is employed and used to evaluate the electrical performance of materials to allow a more efficient means of producing improved performance of planar polymer devices.

The apparatus and method of the present invention allow for evaluation of the electrical performance of candidate materials and enables more efficient means for producing planar polymer devices which have improved characteristics. By selecting polymers which have improved characteristics, the electrical devices which are produced will exhibit preferred properties in both efficiency and utilization.

In a preferred embodiment of the present invention, evaluation of a single film structure between electrodes is obtained. In another preferred embodiment, the present invention uses a single film conductivity to select suitable films for best poling effectiveness in multi-layer devices. In one preferred instance, three layer devices are used.

### DESCRIPTION OF THE DRAWINGS

The present invention is described with reference to the accompanying drawings, in which like reference characters reference like elements, and wherein:

FIG. 1 shows a cross-section of a three-layer device;

FIG. 2 shows a top view of a conductivity test device; and

FIG. 3 shows a cross-section of a conductivity test device.

### DETAILED DESCRIPTION OF THE INVENTION

The benefits and advantages of this invention are obtained by controlling and measuring the characteristics of the conductivity.

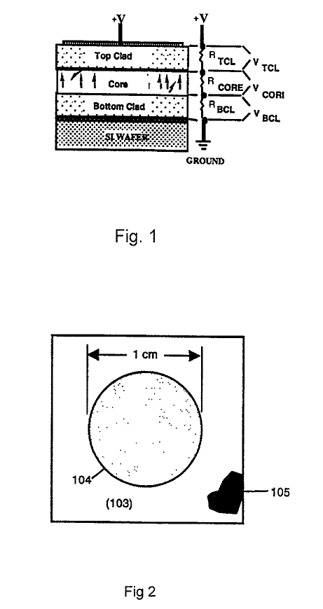

FIG. 1 shows a cross-section of a three-layer device. The device is planar and has a stack of three layers. The core layer contains the chromophore and is sandwiched between two cladding layers. Performance of the modulators is determined by the degree of alignment of the chromophore in the core layer that is given by the formula:

V(core)/V=R(core)/(R(core)+R(TCL)+R(RCL)

Where TCL=top clad layer, core=core layer with chromophore, BCL=bottom clad layer, R=electrical resistance, and V=voltage.

The conductivity of each layer is chosen so that the ratio V(core)/V is a large a possible. The electrical conductivity of each layer at the poling temperature is individually measured.

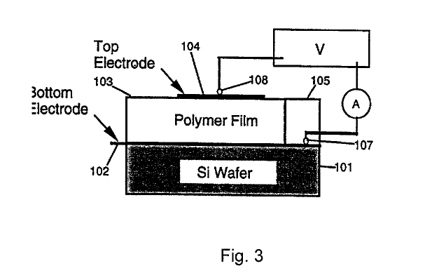

FIG. 2 shows a top view of a conductivity test device used in the present invention. FIG. 3 shows a cross-section of the conductivity test device. This device is made my coating a single polymer film 103 on silicon wafer 101 that has a metal bottom electrode 102. The top electrode 104 is evaporated directly onto the polymer film 103 utilizing a shadow mask to form the 1 cm diameter shown in FIG. 2. A gentle probe 108 makes contact to the top electrode 103. A small area of the polymer film 105 is removed to permit electrical contact by probe 107.

Each conductivity test device is placed on a temperature controlled hot place and is headed to the poling temperature. Voltage V is then applied and the current is measured by ammeter A.

The circuit schematic is shown in FIG. 3.

The conductivity at the poling temperature is defined as the ratio of the current A to the applied voltage V. Various polymer materials can be tested in this manner and selection is made so that the conductivity of the top and bottom cladding layers shown in FIG. 1 are high when compared to the conductivity of the core layer. This provides the highest ratio of V(core)/V.

This process allows materials to be screened and a proper chromphore alignment technique can be identified to improve voltage response of planar polymer modulators.

By the technique of this invention, polymers may be selected to optimize performance. By obtaining a high conductivity so that the voltage of the core is maximized, the polymers can be selected which will have a significant influence on the signal sensitivity and power requirements for high bandwidth signal processing. These characteristics are desirably optimized for satellite and terrestrial applications.

The process of this invention for evaluating the electrical performance of candidate materials enables a more efficient means of producing the best performance of the planar polymer devices.

While the preferred embodiments of the present invention have been described above, it should be understood that they have been presented by way of example only, and not of limitation. It will be apparent to persons skilled in the relevant art that various changes in form and detail can be made therein with departing from the spirit and scope of this invention. Thus the present invention should not be limited by the above-described exemplary embodiments.

What is claimed is:

1. A method of optimizing polymer systems used modulators devices comprising
measuring the conductivity of a first layer by applying a voltage and determining the current;
measuring the conductivity of at least one additional layer by applying a voltage and determining the current;
and comparing the conductivity whereby polymers may be optimized by selecting the highest conductivity.

2. A method of optimizing polymer layers used in modulators comprising
forming a single polymer film between two cladding layers and
measuring the conductivity of the single polymer film whereby polymers may be optimized by selected the highest conductivity.

3. The method of claim 2 whereby the polymer film between two cladding layers is support substrate.

4. The method of claim 3 whereby the support substrate is a silicon wafer.

5. The method of claim 1 whereby the polymer system is heated to the poling temperature.

6. The method of claim 2 whereby the single polymer between two cladding layers is heated to the poling temperture.
